(19) United States
(12) Patent Application Publication
(10) Pub. No.: US 2025/0109482 A1
(43) Pub. Date: Apr. 3, 2025

(54) FORMATION APPARATUS AND METHOD OF HYDROXYAPATITE-CONTAINING THIN FILM

(71) Applicant: Brainy Inc., Chiba (JP)

(72) Inventors: Nobukiyo Tanaka, Okinawa (JP); Masashi Tanaka, Chiba (JP)

(73) Assignee: Brainy Inc., Chiba (JP)

(21) Appl. No.: 18/978,557

(22) Filed: Dec. 12, 2024

Related U.S. Application Data
(63) Continuation of application No. PCT/JP2022/023629, filed on Jun. 13, 2022.

(51) Int. Cl. C23C 14/34; C23C 14/08; C23C 14/50; C23C 14/54

(52) U.S. Cl. CPC C23C 14/34; C23C 14/082; C23C 14/50; C23C 14/542

(57) ABSTRACT

A formation apparatus of a hydroxyapatite-containing thin film includes a sputtering device which forms a thin film of a material including an antibacterial metal and hydroxyapatite on a surface of an object by sputtering, and a hydrothermal treatment device which performs hydrothermal treatment on the object, on which the thin film is formed, using an alkaline solution.

### CROSS-REFERENCE TO RELATED APPLICATIONS

This application is a Continuation Application of PCT Application No. PCT/JP2022/023629, filed Jun. 13, 2022, the entire contents of which are incorporated herein by reference.

### BACKGROUND OF THE INVENTION

1. Field of the Invention

The present invention relates to an apparatus and a method for forming a hydroxyapatite-containing thin film.

2. Description of the Related Art

Hydroxyapatite (hereinafter, referred to as HA) is expressed as, for example, Ca₁₀(PO₄)₆ (OH)₂.

HA is chemically and structurally similar to human bone, and thus has a high affinity for bone and high biocompatibility.

HA may not have sufficient mechanical strength by itself. For this reason, HA may be used, for example, to coat a surface of a metal having greater mechanical strength than that of HA, such as in an artificial joint or a dental implant.

### BRIEF SUMMARY OF THE INVENTION

A formation apparatus of a hydroxyapatite-containing thin film according to one embodiment includes a sputtering device which forms a thin film of a material including an antibacterial metal and hydroxyapatite on a surface of an object by sputtering, and a hydrothermal treatment device which performs hydrothermal treatment on the object, on which the thin film is formed, using an alkaline solution.

A formation method of a hydroxyapatite-containing thin film according to another embodiment includes forming a thin film of a material including an antibacterial metal and hydroxyapatite on a surface of an object by sputtering, and performing hydrothermal treatment on the object, on which the thin film is formed, using an alkaline solution.

According to the embodiments of the present invention, a hydroxyapatite-containing thin film which has an affinity for bone and antibacterial properties and which does not separate or dissolve from a surface of an object can be formed on the surface of the object.

Additional objects and advantages of the

invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a block diagram illustrating an example of a formation apparatus of an HA thin film according to a first embodiment.

FIG. 2 is a flowchart illustrating an example of a formation process performed by the formation apparatus according to the first embodiment.

FIG. 3 is a flowchart illustrating an example of sputtering.

FIG. 4 is a flowchart illustrating an example of hydrothermal treatment.

FIG. 5 is a diagram illustrating an example of first to fourth samples generated by the formation process according to the first embodiment.

FIG. 6 is a diagram illustrating an example of an (the number of atoms of silver/the number of atoms of calcium) preparation amount, an atomic number ratio (the number of atoms of silver/the number of atoms of calcium) before hydrothermal treatment, and an atomic number ratio (the number of atoms of silver/the number of atoms of calcium) after hydrothermal treatment for each of the first to fourth samples.

FIG. 7 is a graph illustrating an example of (the number of atoms of silver/the number of atoms of calcium) before hydrothermal treatment and (the number of atoms of silver/the number of atoms of calcium) after hydrothermal treatment for each of the first to fourth samples.

FIG. 8 is a diagram illustrating an example

of an antibacterial activity value of a titanium substrate on which a thin film is not formed, antibacterial activity values of the first to fourth samples before hydrothermal treatment, and antibacterial activity values of the first to fourth samples after hydrothermal treatment.

FIG. 9 is a diagram illustrating an example of conditions for studying changes in the resistance values in the cases where hydrothermal treatment is performed and it is not performed.

FIG. 10 is a graph illustrating an example of the relationship between atomic number ratios Ag/Ca which is calculated by (the number of atoms of silver/the number of atoms of calcium), resistance values before hydrothermal treatment, and resistance values after hydrothermal treatment.

FIG. 11 is a diagram illustrating an example of resistance values before hydrothermal treatment and resistance values after hydrothermal treatment for each of the first to fourth samples.

FIG. 12 is a block diagram illustrating an example of a configuration of a preparation apparatus according to a second embodiment.

FIG. 13 is a conceptual diagram illustrating an example of a mixed state of calcium hydroxide and first mixed liquid including phosphoric acid and silver nitrate by the preparation apparatus according to the second embodiment.

FIG. 14 is a flowchart illustrating an example of a suspension preparation method executed by the preparation apparatus according to the second embodiment.

FIG. 15 is a conceptual diagram illustrating an example of spontaneous sedimentation in the suspension preparation method according to the second embodiment.

FIG. 16 is a diagram illustrating an example of the relationship of pH and color of solution.

FIG. 17 is a diagram illustrating an example of results of applying gray AgHA, light gray AgHA, and white AgHA to nonwoven fabric and investigating antibacterial activity values using Escherichia coli.

FIG. 18 is a graph illustrating an example of deodorizing effects of a nonwoven fabric coated with HA solution having a concentration of 0.5% by weight, a nonwoven fabric coated with light gray AgHA solution having a concentration of 0.5% by weight, and a nonwoven fabric coated with white AgHA solution having a concentration of 0.5% by weight.

FIG. 19 is a conceptual diagram illustrating an example of a mixed state of second mixed liquid including calcium hydroxide and silver nitrate, and phosphoric acid by a preparation apparatus according to a third embodiment.

FIG. 20 is an enlarged view illustrating an example of a state of a thin film in a case where pH of liquid used for hydrothermal treatment is 10.5.

FIG. 21 is an enlarged view illustrating an example of a state of a thin film in a case where pH of liquid used for hydrothermal treatment is 9.5.

FIG. 22 is a graph illustrating an example of the relationship between immersion periods and thin film residual rates in a case where a thin film before hydrothermal treatment is immersed in liquid, and an example of the relationship between immersion periods and thin film residual rates in the case where a thin film after hydrothermal treatment is immersed in the liquid.

### DETAILED DESCRIPTION OF THE INVENTION

Embodiments of the present invention will be described hereinafter with reference to the drawings.

In the following description, the same or substantially the same functions and structural elements are denoted by the same reference signs, and explanations thereof will be omitted or will be made only when necessary.

### First Embodiment

In a first embodiment, an HA thin film containing an antibacterial metal is formed by sputtering and hydrothermal treatment (hydrothermal crystallization).

Sputtering is a method of depositing a raw material called a target onto an object, for example, a substrate, using plasma.

Sputtering includes direct current sputtering and radio frequency sputtering. To sputter an insulating material, such as HA, radio frequency sputtering is preferable to direct current sputtering. Accordingly, in the first embodiment, radio frequency sputtering is performed.

In the first embodiment, the antibacterial

metal may be a heavy metal. The antibacterial heavy metals include, for example, silver, copper, palladium, platinum, cadmium, nickel, cobalt, zinc, manganese, thallium, lead, and mercury. The first embodiment illustrates, as an example, a case where a thin film is formed of an Ag/HA composite material prepared (produced) by mixing HA with silver (Ag) of the antibacterial metals. Note that a thin film also can be formed of a composite material prepared by mixing HA with another antibacterial metal, for example, copper, by making a modification to the first embodiment as appropriate.

More specifically, in the first embodiment, an HA thin film doped with Ag is formed on a surface of an object, by sputtering and hydrothermal treatment, using an Ag/HA composite material prepared by mixing Ag powder and HA powder. In the first embodiment, hydrothermal treatment is performed on the thin film formed by sputtering, thereby preventing the thin film from dissolving in a living body.

In the first embodiment, Ag-containing HA (hereinafter, referred to as AgHA), prepared by doping HA with Ag, may be used instead of an Ag/HA composite material. A specific example of AgHA preparation will be explained in a second embodiment, which will be described later.

In the first embodiment, the mixing ratio between Ag and HA in the Ag/HA composite material is controlled to thereby control the composition of Ag in the thin film, for example, the ratio between Ag and HA in the thin film formed on the object.

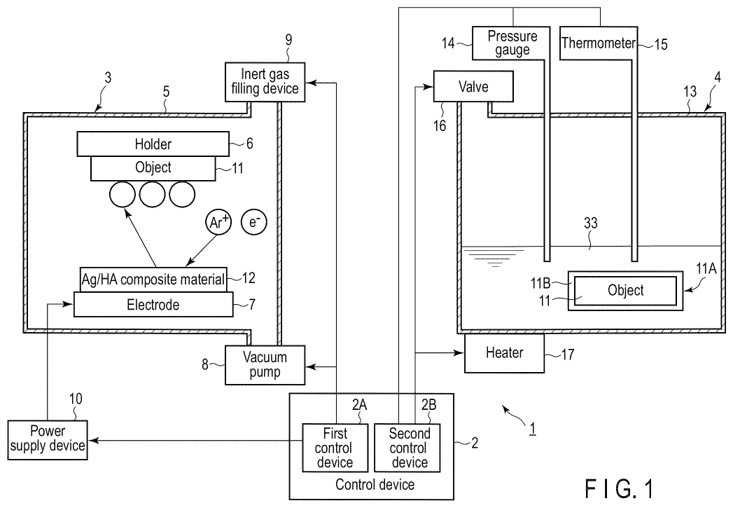

FIG. 1 is a block diagram illustrating an example of a formation apparatus 1 of an HA thin film according to the first embodiment.

The formation apparatus 1 includes a control device 2, a sputtering device 3, and a hydrothermal treatment device 4.

The control device 2 includes a first control device 2A which controls the sputtering device 3 and a second control device 2B which controls the hydrothermal treatment device 4.

To be specific, the first control device 2A transmits control signals to a vacuum pump 8, an inert gas filling device 9, and a power supply device 10 in the sputtering device 3.

The second control device 2B receives a signal indicating pressure from a pressure gauge 14 in the hydrothermal treatment device 4 and receives a signal indicating temperature from a thermometer 15 in the hydrothermal treatment device 4. In addition, the second control device 2B transmits a control signal to at least one of a valve 16 and a heater 17, on the basis of the pressure indicated by the signal received from the pressure gauge 14 and the temperature indicated by the signal received from the thermometer 15.

The control device 2 may perform various control processes by, for example, causing a processor to execute a program stored in a storage device. The first control device 2A and the second control device 2B may be separate structures or may be an integrated structure.

The sputtering device 3 includes a first container 5, a holder 6, an electrode 7, the vacuum pump 8, the inert gas filling device 9, and the power supply device 10.

The first container 5 is, for example, a vacuum chamber.

The holder 6 is provided in the first container 5. An object 11, on which a thin film is to be formed, is provided on the holder 6 side. The potential of the holder 6 is floating.

The electrode 7 is provided in the first container 5. An Ag/HA composite material 12, which is a target of sputtering, is provided on the electrode 7 side. The electrode 7 switches between positive and negative poles at a high frequency (a determined frequency or higher). The frequency at which the positive and negative poles of the electrode 7 switches may be, for example, 13.56 MHZ.

For example, the holder 6 and the electrode 7 are arranged to face each other. The object 11 may be provided on a surface of the holder 6 that faces the electrode 7. The Ag/HA composite material 12 may be provided on a surface of the electrode 7 that faces the holder 6.

The vacuum pump 8 expels air in the first container 5 on the basis of a signal from the first control device 2A.

The inert gas filling device 9 fills the first container 5 with an inert gas on the basis of a signal from the first control device 2A. This creates an inert gas atmosphere in the first container 5.

The first embodiment illustrates a case where argon (Ar) is used as the inert gas, as an example. In this case, an Ar atmosphere is created in the first container 5. However, the other inert gas may be used instead of Ar.

The power supply device 10 applies a high voltage to the electrode 7 at a high frequency and causes discharge on the basis of a signal from the first control device 2A.

The atomic number ratio Ca/P of calcium (Ca) to phosphorus (P) of calcium phosphate adhering to the surface of the object 11 changes according to the discharge pressure and discharge power in the first container 5. The first control device 2A controls the vacuum pump 8 and the inert gas filling device 9 to adjust the pressure in the first container 5, and controls the power supply device 10 to adjust the power, executing control to make the atomic number ratio Ca/P range from 1.0 to 3.0.

The sputtering device 3 applies a high voltage to the Ag/HA composite material 12 and causes discharge in the first container 5 filled with Ar. This atomizes Ar, and atomized Ar collides with the Ag/HA composite material 12. Then, atoms of the Ag/HA composite material 12 are ejected, and Ag and HA adhere to the object 11. As a result, a thin film 11B containing Ag and HA is formed on the object 11. The atomic number ratio between the numbers of atoms of Ag and Ca and the atomic number ratio Ca/P change according to the discharge pressure and discharge power in the sputtering performed by the sputtering device 3.

The formation of the thin film 11B will be described more specifically. In the sputtering device 3, first, the vacuum pump 8 and the inert gas filling device 9 creates an Ar atmosphere in the first container 5. Then, the power supply device 10 applies a high voltage to the electrode 7 at a high frequency, causing an electron to collide with the Ar gas in the first container 5 to form Ar+ and e−. Subsequently, Ar+ is attracted toward the negatively charged Ag/HA composite material 12. Then, Ar+ collides with the Ag/HA composite material 12, and Ag and HA eject from the Ag/HA composite material 12 and adhere to the object 11.

In the first embodiment, the first control device 2A controls sputtering to make the thickness of the thin film 11B range, for example, from 0.1 μm to 10 μm. If the thin film 11B is too thick, the thin film 11B may peel off the object 11 due to internal stress. If the thin film 11B is too thin, the thin film 11B may dissolve, for example, before a bone is formed in a living body. Making the thickness of the thin film 11B range, for example, from 0.1 μm to 10 μm as in the first embodiment can prevent the peeling and dissolution of the thin film 11B.

The hydrothermal treatment device 4 includes a second container 13, the pressure gauge 14, the thermometer 15, the valve 16, and the heater 17. For example, an autoclave may be used as the hydrothermal treatment device 4. The hydrothermal treatment device 4 performs hydrothermal treatment, in which an object 11A, prepared by forming the thin film 11B containing Ag and HA on the object 11, is placed under a high temperature and a high pressure for a predetermined duration, and crystallizes the thin film 11B. If HA is crystallized by heat treatment in air, it needs to be heated at a high temperature, for example, 700° C. or higher. If heating is thus performed at a high temperature of 700° C. or higher, an HA thin film may peel off due to the difference in the coefficients of thermal expansion between titanium and HA. In the first embodiment, hydrothermal treatment is used to enable crystallization, for example, at a temperature of 180° C. or lower, and it is therefore possible to prevent the thin film 11B from peeling off.

The dissolution of the thin film 11B in a living body can be prevented by performing hydrothermal treatment on the thin film 11B after sputtering.

The second container 13 accommodates a liquid 33 (for example, an alkaline solution) and the object 11A, on which the thin film 11B of the Ag/HA composite material 12 is formed. The second container 13 is, for example, a pressure-resistant hermetically sealed container, and is formed of, for example, stainless steel.

The pH of the alkaline solution used for hydrothermal treatment may range, for example, from 8 to 12. The pH of the alkaline solution should preferably range from 9 to 11. The pH of the alkaline solution can be adjusted by, for example, adding an alkaline substance, such as sodium hydroxide (NaOH), potassium hydroxide (KOH), or ammonium hydroxide (NH₄OH), as appropriate.

If an element is added to hydroxyapatite to form a thin film and then hydrothermal treatment is performed, the element in the thin film may dissolve during the hydrothermal treatment.

For example, if hydrothermal treatment is performed using a neutral solution, not an alkaline solution, the thin film dissolves in the neutral solution during the hydrothermal treatment.

For example, if hydrothermal treatment is performed on a strontium-apatite thin film, strontium is mixed into an alkaline solution to prevent strontium from dissolving from the strontium-apatite thin film.

However, in the case of hydrothermal treatment performed on the thin film 11B containing Ag and HA according to the first embodiment, using an alkaline solution, it is possible to prevent Ag from dissolving from the thin film 11B during the hydrothermal treatment, even if Ag is not mixed into the alkaline solution.

Note that in the first embodiment, if Ag is mixed into the alkaline solution, Ag may precipitate on the inner wall of the second container 13 during the hydrothermal treatment. However, in the first embodiment, since Ag is not mixed into the alkaline solution, it is possible to prevent Ag from precipitating on the inner wall of the second container 13 during the hydrothermal treatment.

The pressure gauge 14 measures the pressure of gas in the second container 13, and transmits a signal indicating the pressure to the second control device 2B in the control device 2.

The thermometer 15 measures the temperature of at least one of the liquid or the gas in the second container 13 and transmits a signal indicating the temperature to the second control device 2B in the control device 2.

The second control device 2B generates a signal controlling the heater 17 and transmits the signal to the heater 17, on the basis of the pressure indicated by the signal received from the pressure gauge 14, during hydrothermal treatment. In this manner, in the first embodiment, the pressure in the second container 13 is adjusted by temperature during hydrothermal treatment. Adjusting the pressure in the second container 13 by temperature, not by opening and closing the valve 16, during hydrothermal treatment can prevent the alkaline solution from spouting out from the second container 13 due to the loosening of the valve 16 during the hydrothermal treatment, and can prevent the alkaline solution from decreasing.

The second control device 2B generates a signal controlling the heater 17 and transmits the signal to the heater 17, on the basis of the temperature indicated by the signal received from the thermometer 15.

The second control device 2B performs hydrothermal treatment, for example, at a temperature of 100° C. to 180° C. and for a duration of 12 hours to 72 hours. The valve 16 changes its open/closed state on

the basis of a signal from the second control device 2B.

The heater 17 heats the gas and the liquid in the second container 13 on the basis of a signal from the second control device 2B. The temperature in the second container 13 thereby can be adjusted. During hydrothermal treatment, the temperature in the second container 13 is high.

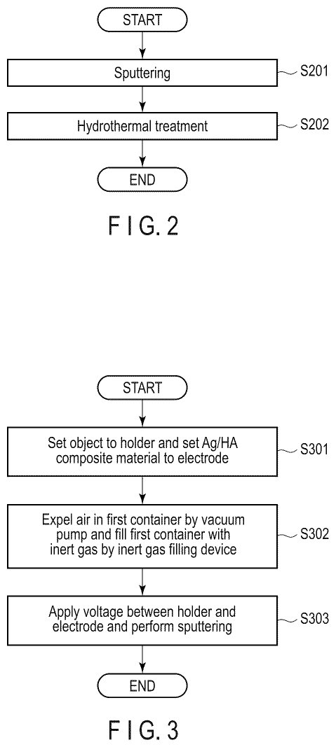

FIG. 2 is a flowchart illustrating an example of a formation process performed by the formation apparatus 1 according to the first embodiment.

In step S201, the first control device 2A controls the sputtering device 3 to perform sputtering, and generates the object 11A with the thin film 11B formed on the surface of the object 11.

In step S202, the second control device 2B controls the hydrothermal treatment device 4 and crystallizes the thin film 11B of the object 11A by hydrothermal treatment.

FIG. 3 is a flowchart illustrating an example of sputtering.

In step S301, the object 11 is placed on the holder 6 side and the Ag/HA composite material 12 is placed on the electrode 7 side, in the first container 5.

In step S302, the first control device 2A operates the vacuum pump 8, and thereby expels air in the first container 5. In addition, the first control device 2A operates the inert gas filling device 9, and thereby fills the first container 5 with an inert gas.

In step S303, the first control device 2A controls the power supply device 10 to apply a high voltage of a high frequency to the electrode 7, and performs sputtering. As a result, the object 11A, with the thin film 11B containing Ag and HA formed on the surface of the object 11, is generated.

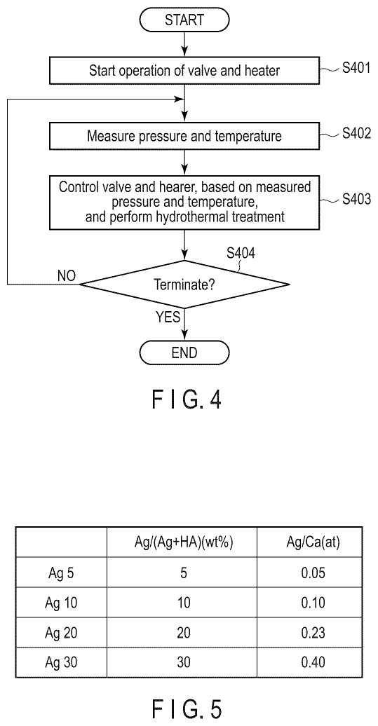

FIG. 4 is a flowchart illustrating an example of hydrothermal treatment.

In step S401, the second control device 2B operates the valve 16 and the heater 17. More specifically, the second control device 2B sets the valve 16 to a closed state, and heats the gas and the liquid in the second container 13 by the heater 17.

In step S402, the pressure gauge 14 measures the pressure of the gas in the second container 13, and transmits a signal indicating the pressure measured by the pressure gauge 14 to the second control device 2B. The second control device 2B receives the signal indicating the pressure of the gas in the second container 13 measured by the pressure gauge 14 from the pressure gauge 14. In addition, the thermometer 15 measures the temperature of at least one of the gas or the liquid in the second container 13, and transmits a signal indicating the temperature measured by the thermometer 15 to the second control device 2B. The second control device 2B receives the signal indicating the temperature in the second container 13 measured by the thermometer 15 from the thermometer 15.

In step S403, the second control device 2B controls the states of the valve 16 and the heater 17, on the basis of the pressure indicated by the signal received from the pressure gauge 14 and the temperature indicated by the signal received from the thermometer 15. As a result, the thin film 11B formed on the surface of the object 11 can be crystallized. Note that the second control device 2B may control the temperature and the pressure in the second container 13 by keeping the closed state of the valve 16 and changing the operation of the heater 17 during hydrothermal treatment.

In step S404, the second control device 2B determines whether to terminate hydrothermal treatment. For example, the second control device 2B determines to terminate hydrothermal treatment, when a predetermined period of time has elapsed.

If the second control device 2B determines not to terminate hydrothermal treatment, the process by the hydrothermal treatment device 4 proceeds to step S402.

If the second control device 2B determines to terminate hydrothermal treatment, the process by the hydrothermal treatment device 4 terminates.

The following description explains that the thin film 11B formed on the surface of the object 11 by hydrothermal treatment does not separate or dissolve from the surface.

FIG. 5 is a diagram illustrating an example of first to fourth samples Ag5, Ag10, Ag20, and Ag30 generated by the formation process according to the first embodiment.

Each of the first to fourth samples Ag5,Ag10, Ag20, and Ag30 of FIG. 5 is generated by forming the thin film 11B containing Ag and HA on a Ti substrate by the formation process according to the first embodiment. The reason why Ti is used for the substrate is that Ti is used as, for example, a material for an artificial joint or a dental implant.

For the Ag/HA composite material 12, {the weight of Ag/(the weight of Ag+the weight of HA)} is calculated on the basis of the weight of Ag and the weight of HA, and the calculated value is defined as the weight ratio. In the following description, {the weight of Ag/(the weight of Ag+the weight of HA)} is expressed as Ag/(Ag+HA).

For the first sample Ag5, the weight ratio is 5% by weight (0.05).

For the Ag/HA composite material 12, (the number of atoms of Ag/the number of atoms of Ca) is calculated on the basis of the number of atoms of Ag and the number of atoms of Ca, and the calculated value is defined as the atomic number ratio. In the following description, (the number of atoms of Ag/the number of atoms of Ca) is expressed as Ag/Ca.

For the first sample Ag5, the atomic number ratio Ag/Ca of Ag to Ca is 0.05.

For the second sample Ag10, the weight ratio calculated as Ag/(Ag+HA) is 10% by weight.

For the second sample Ag10, the atomic number ratio Ag/Ca of Ag to Ca is 0.10.

For the third sample Ag20, the weight ratio calculated as Ag/(Ag+HA) is 20% by weight.

For the third sample Ag20, the atomic number ratio Ag/Ca of Ag to Ca is 0.23.

For the fourth sample Ag30, the weight ratio calculated as Ag/(Ag+HA) is 30% by weight.

For the fourth sample Ag30, the atomic number ratio Ag/Ca of Ag to Ca is 0.40.

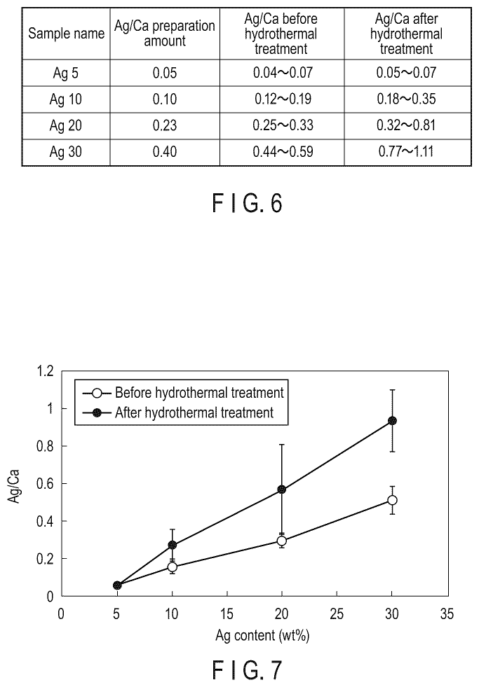

FIG. 6 is a diagram illustrating an example of the Ag/Ca preparation amount, the atomic number ratio Ag/Ca before hydrothermal treatment, and the atomic number ratio Ag/Ca after hydrothermal treatment for each of the first to fourth samples Ag5, Ag10, Ag20, and Ag30.

In FIG. 6, the Ag/Ca preparation amount represents the atomic number ratio between the preparation amounts of Ag and Ca.

FIG. 7 is a graph illustrating an example of (the number of atoms of Ag/the number of atoms of Ca) before hydrothermal treatment and (the number of atoms of Ag/the number of atoms of Ca) after hydrothermal treatment for each of the first to fourth samples.

From FIG. 7, a change of the atomic number ratio Ag/Ca before and after hydrothermal treatment with respect to the preparation amount of Ag can be understood.

Ag, which is metallic atoms, has a weaker bond than those of Ca and P, and thus is easily sputtered. Thus, in the first to fourth samples Ag5, Ag10, Ag20, and Ag30, the atomic number ratio Ag/Ca after sputtering and before hydrothermal treatment tends to increase more than the Ag/Ca preparation amount.

During hydrothermal treatment, Ca and P slightly dissolve and Ag is less dissoluble than Ca and P. For this reason, in the first to fourth samples Ag5, Ag10, Ag20, and Ag30, the atomic number ratio Ag/Ca after hydrothermal treatment tends to further increase more than the Ag/Ca preparation amount and the atomic number ratio Ag/Ca before hydrothermal treatment.

From FIG. 6 and FIG. 7, it is understood that the atomic number ratio Ag/Ca after sputtering and before hydrothermal treatment and the atomic number ratio Ag/Ca after hydrothermal treatment increase more than the Ag/Ca preparation amount. In addition, since the atomic number ratio Ag/Ca rises after hydrothermal treatment, it is understood that the dissolution of Ag is suppressed in the first embodiment.

When Ca and P dissolve, Ag also dissolves in due course. However, in the first embodiment, an alkaline solution is used as the solution for hydrothermal treatment, thereby preventing Ca and P from dissolving and further preventing Ag from dissolving.

As the Ag/Ca preparation amount increases, the atomic number ratios Ag/Ca before and after hydrothermal treatment increase. Accordingly, in the first embodiment, it is preferable that the Ag/Ca preparation amount be determined in consideration of an increase of the Ag ratio.

As described above, the Ag in the thin film 11B, formed by the formation process according to the first embodiment, does not separate into the liquid 33 from the surface of the object 11 and remains stable during hydrothermal treatment. In addition, the Ag in the thin film 11B does not dissolve and remains stable.

The antibacterial properties of the first to fourth samples Ag5, Ag10, Ag20, and Ag30 including the thin film 11B generated by the first embodiment will be described hereinafter.

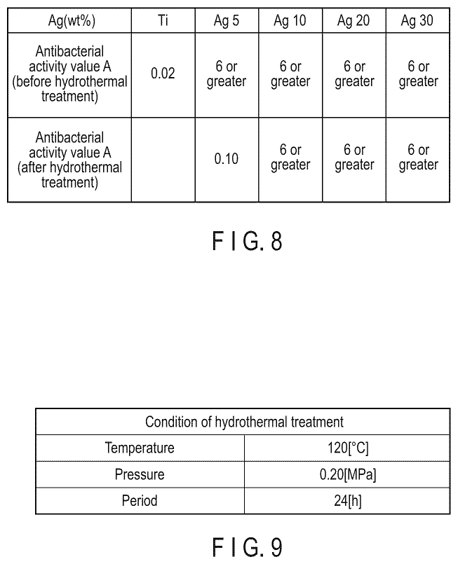

FIG. 8 is a diagram illustrating an example of the antibacterial activity values A of the Ti substrate on which the thin film 11B is not formed and the first to fourth samples Ag5, Ag10, Ag20, and Ag30 before hydrothermal treatment, and the antibacterial activity values A of the first to fourth samples Ag5, Ag10, Ag20, and Ag30 after hydrothermal treatment. The first to fourth samples Ag5, Ag10, Ag20, and Ag30 in FIG. 8 has a film thickness of 1.0 μm.

If the antibacterial activity values A are 2.0 or greater but less than 3.0, an antibacterial effect is observed. If the antibacterial activity values A are 3.0 or greater, a strong antibacterial effect is observed.

As illustrated in FIG. 8, Ti has no effective antibacterial effect. All of the antibacterial activity values A of the first to fourth samples Ag5, Ag10, Ag20, and Ag30 before hydrothermal treatment are 6 (first threshold value) or greater. Accordingly, the first to fourth samples Ag5, Ag10, Ag20, and Ag30 before hydrothermal treatment have a strong antibacterial effect.

After hydrothermal treatment, the antibacterial activity value A of the first sample Ag5decreases to 0.1, and the antibacterial effect of the first sample Ag5 is lost.

However, all of the antibacterial activity values A of the second to fourth samples Ag10, Ag20, and Ag30 after hydrothermal treatment are 6 (first threshold value) or greater. Accordingly, the second to fourth samples Ag10, Ag20, and Ag30 after hydrothermal treatment have a strong antibacterial effect.

Referring to FIG. 5 above and FIG. 8, it is understood that the thin film 11B has antibacterial properties, if the atomic number ratio Ag/Ca of Ag to Ca is greater than 0.05 but less than 0.1. In addition, it is understood that the thin film 11B has a strong antibacterial effect, if the atomic number ratio Ag/Ca of Ag to Ca is 0.1 or greater.

Resistance values in cases where hydrothermal treatment according to the first embodiment is performed and it is not performed will be described hereinafter.

FIG. 9 is a diagram illustrating an example of conditions for studying changes in the resistance values in the cases where hydrothermal treatment is performed and it is not performed. In this study, the film thickness of the first to fourth samples Ag5, Ag10, Ag20, and Ag30 was set to 1.0 μm.

In this study, hydrothermal treatment was performed at a temperature of 120° C., at a pressure of 0.20 MPa, and for 24 hours.

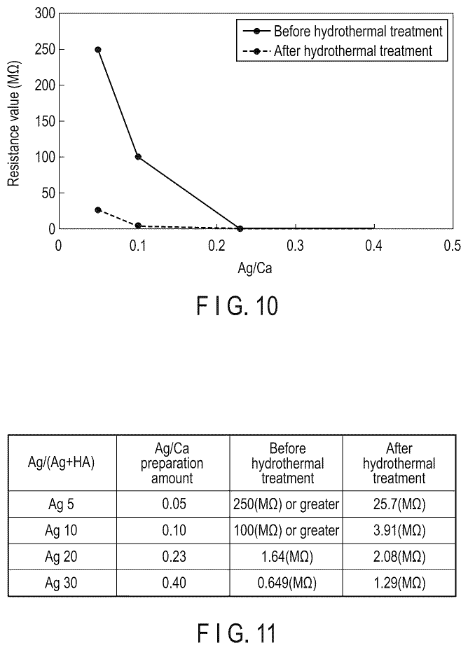

FIG. 10 is a graph illustrating an example of the relationship between the atomic number ratio Ag/Ca and the resistance values before and after hydrothermal treatment. The horizontal axis of FIG. 10 represents the atomic number ratio Ag/Ca, and the vertical axis represents the resistance values.

As the atomic number ratio Ag/Ca decreases, both the resistance values before and after hydrothermal treatment increases.

If the atomic number ratio Ag/Ca is small (approximately, 0.23 or less), the resistance value after hydrothermal treatment is less than the resistance value before hydrothermal treatment.

FIG. 11 is a diagram illustrating an example of the resistance values before and after hydrothermal treatment for each of the first to fourth samples Ag5, Ag10, Ag20, and Ag30.

As seen in FIG. 11, as the Ag weight ratio increases and the atomic number ratio Ag/Ca increases, the resistance values decrease.

In addition, the resistance values of Ag20 and Ag30 decrease more significantly than those of Ag5 and Ag10. In other words, if the weight ratio calculated as Ag/(Ag+HA) is 20% by weight or greater, the resistance values decrease more significantly than if the weight ratio calculated as Ag/(Ag+HA) is less than 20% by weight, and the resistance values can be suppressed to be less than a second threshold value (for example, 2.08 MΩ).

The above-described results of FIG. 10 and FIG. 11 show that the insulation resistance value of the object 11A can be reduced by increasing the content of Ag. Accordingly, the electrical resistivity can be controlled by controlling the amount of Ag in the thin film 11B. Therefore, the object 11A according to the first embodiment can be applied not only to products used for living bodies, for example, artificial joints or dental implants, but also to industrial products that require reduced electrical resistivity.

Effects of the formation apparatus 1 and the formation process according to the above-described first embodiment will be described.

In the first embodiment, the thin film 11B can be doped with Ag having excellent antibacterial properties, using sputtering and hydrothermal treatment.

In the first embodiment, the thin film 11B having a high affinity for bone and strong antibacterial properties can be formed by controlling the doping amount of Ag appropriately.

In the first embodiment, the composition of the thin film 11B can be controlled by changing the mixing ratio between Ag and HA.

In the first embodiment, the loss of Ag can be suppressed even if hydrothermal treatment is performed.

In the first embodiment, strong antibacterial properties of the first threshold value or greater can be achieved by making the weight ratio calculated as Ag/(Ag+HA) 10% by weight or greater.

In the first embodiment, the resistance value of the thin film 11B decreases significantly, if the weight ratio calculated as Ag/(Ag +HA) is 20% by weight or greater. Accordingly, in the first embodiment, the resistance value of the thin film 11B can be controlled by controlling the doping amount of Ag, and for example, a resistance value less than the second threshold value can be achieved.

As a method for HA coating, not only sputtering, but also a plasma spraying method or a flame spraying method, for example, can be used.

Sputtering used in the first embodiment can achieve precise and uniform thin film coating, compared to the plasma spraying method and the flame spraying method. Moreover, sputtering used in the first embodiment can strengthen the bonding force between the object 11 and the thin film 11B, compared to the plasma spraying method and the flame spraying method. More specifically, if a film is formed by the plasma spraying method or the flame spraying method, the film has a film thickness of, for example, 40 μm or greater, and may break, resulting in a decrease in the adhesion between an object and the film. In contrast, if the thin film 11B is formed on the surface of the object 11 by sputtering as in the first embodiment, the thin film 11B can be formed to have, for example, a thickness of approximately 1 μm to 2 μm, and the thin film 11B can be prevented from peeling off the object 11. Therefore, in the first embodiment, it is unnecessary to perform surface roughening on the surface of the object 11, and the process can be simplified.

If hydrothermal treatment is not performed after sputtering, the thin film 11B may dissolve in a living body. However, in the first embodiment, hydrothermal treatment is performed after the thin film 11B is formed on the surface of the object 11 by sputtering. This can increase the strength of the thin film 11B and can prevent the thin film 11B from dissolving.

If the thin film 11B is too thick, the thin film 11B may peel off the object 11 due to internal stress. If the thin film 11B is too thin, the thin film 11B may dissolve, for example, before a bone is formed in a living body. Forming the thin film 11B to make its thickness range, for example, from 0.1 μm to 10 μm as in the first embodiment can prevent the peeling and the dissolution of the thin film 11B.

In the first embodiment, hydrothermal treatment is performed on the thin film 11B containing Ag and HA, using an alkaline solution. Thus, even if Ag is not mixed into the alkaline solution, Ag can be prevented from dissolving from the thin film 11B during hydrothermal treatment.

If an artificial joint, an artificial organ, or a dental implant is embedded in a living body, an infectious disease or complications may occur. Moreover, a biofilm may be formed by an infectious disease, which makes an antibacterial agent less effective. Metal ions having antibacterial properties include, for example, an Ag ion or a Cu ion. In particular, Ag is effective as an antibacterial material that is safe for the human body, and can reduce the hazard of microbes to the human body. In the first embodiment, the thin film 11B formed by sputtering is doped with Ag, which has high antibacterial properties. This can suppress the occurrence of an infectious disease and complications.

### Second Embodiment

In the above-described first embodiment, it has been explained that sputtering is performed using the Ag/HA composite material 12, prepared by mixing Ag and HA. It also has been explained that AgHA can be used instead of the Ag/HA composite material 12.

In the second embodiment, a preparation apparatus and method of AgHA, which can be used instead of the Ag/HA composite material 12, will be described.

An example of the HA preparation method is a solution method. In general, HA is transported, sold, and used in the form of dry powders. HA agglomerates when it dries. The particle size of agglomerated HA is a micro-size.

In the second embodiment, the preparation apparatus and method for preparing HA containing an antibacterial metal that has a great bacterial inhibition effect and deodorant effect, using the solution method, will be described. More specifically, the second embodiment illustrates the preparation apparatus and method for preparing light gray or white HA containing an antibacterial metal by controlling a pH (hydrogen ion concentration index).

AgHA in an AgHA suspension prepared according to the second embodiment can remain nano-sized.

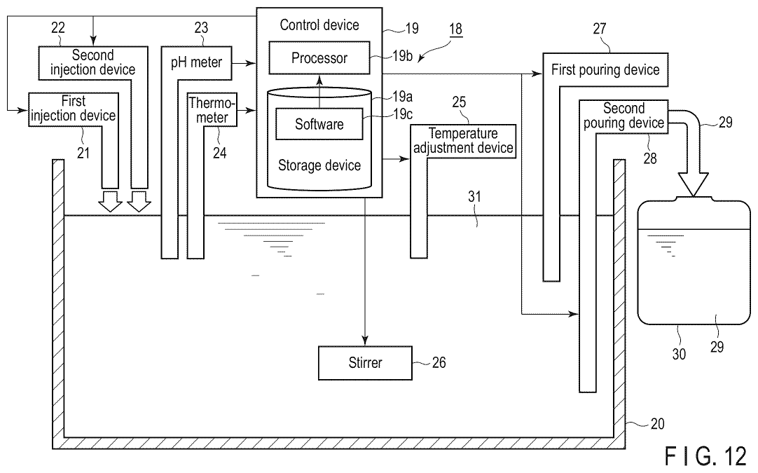

FIG. 12 is a block diagram illustrating an example of a configuration of a preparation apparatus 18 according to the second embodiment.

The preparation apparatus 18 prepares light gray or white AgHA by injecting (for example, dropping) a first mixed liquid (solution) including phosphoric acid and silver nitrate into calium hydroxide, and by controlling based on pH of solution including the calium hydroxide and the first mixed liquid. However, CuHA may be prepared using copper nitrate or copper sulfate instead of the silver nitrate.

Alternatively, the preparation apparatus 18 may prepare light gray or white AgHA by injecting a mixed liquid of silver oxide, nitric acid, and phosphoric acid into calcium hydroxide. When using a mixed liquid of silver oxide and phosphoric acid without containing nitric acid, it is difficult to prepare light gray or white AgHA. However, when a mixed liquid of silver oxide, nitric acid, and phosphoric acid is used, light gray or white AgHA can be prepared.

However, when the mixed liquid includes nitric acid, the hydrogen ions included in the mixed liquid increase. For this reason, when injecting a mixed liquid including silver oxide, nitric acid, and phosphoric acid into calcium hydroxide, the preparation apparatus 18 uses a synthesis condition that is lower pH than when using the first mixed liquid including the phosphoric acid and the silver nitrate.

The preparation apparatus 18 includes a control device 19, a first container 20, a first injection device 21, a second injection device 22, a pH (hydrogen ion concentration index) meter 23, a thermometer 24, a temperature adjustment device 25, a stirrer 26, a first pouring (extraction) device 27, and a second pouring device 28. Light gray or white AgHA suspension 29 prepared and concentrated by the preparation apparatus 18 is included in a second container 30.

Note that the various devices configuring the preparation apparatus 18 may be combined as appropriate. For example, the pH meter 23 and the thermometer 24 may be one device. For example, the first pouring device 27 and the second pouring device 28 may be one pump.

The various devices configuring the preparation apparatus 18 may also be separated as appropriate. For example, the first container 20 may be divided into a container used for dropping first mixed liquid including phosphoric acid and silver nitrate into calcium hydroxide and a container for spontaneous sedimentation of solution 31 which is a mixture of calcium hydroxide and the first mixed liquid.

The control device 19 receives a signal indicating a pH measured by the pH meter 23 and a signal indicating a temperature measured by the thermometer 24.

Based on the pH indicated by the signal received from the pH meter 23 and the temperature indicated by the signal received from the thermometer 24, the control device 19 controls the concentration of calcium hydroxide to be injected into the first container 20 by the first injection device 21, at least one of the concentration or the injection rate (e.g. dropping rate) of the first mixed liquid to be injected (e.g. dropped) into the first container 20 by the second injection device 22, the pH of the solution 31 (synthesis pH), and the temperature management of the solution 31 during AgHA synthesis and spontaneous sedimentation by the temperature adjustment device 25.

The control device 19 may perform control to intentionally prepare calcium-deficient AgHA by additionally dropping the first mixed liquid after dropping the first mixed liquid and lowering the pH of the solution 31.

In the second embodiment, the control device 19 controls the concentration of calcium hydroxide so that the concentration of calcium hydroxide is within a first range. The first range may be, for example, 0.01% or more and 50% or less.

The control device 19 controls the concentration of the first mixed liquid so that the concentration of phosphoric acid is within a second range, and the concentration of silver nitrate is within a third range. The second range may be, for example, 0.01% or more and 50% or less. The third range may be, for example, 0.01% or more and 50% or less.

The control device 19 controls the injection rate of the first mixed liquid so that the injection rate of the first mixed liquid with respect to AgHA preparation amount is within a fourth range. The fourth range may be, for example, 0.01 ml/min/g or more and 100 ml/min/g or less. The fourth range may preferably be, such as, 0.1 ml/min/g or more and 10 ml/min/g or less.

The control device 19 controls the injection amount of at least one of calcium hydroxide or the first mixed liquid so that the pH of the solution 31 in the first container 20 is within a fifth range. The fifth range may be, for example, pH at which light gray or white AgHA is prepared.

AgHA has a color such as brown, gray, light gray, or white. In the second embodiment, the control device 19 controls pH of the solution 31 in the first container 20 and controls the amount of injection of the first mixed liquid so that the solution 31 in the first container 20 is light gray or white.

More specifically, the control device 19 may execute control so that the pH of the solution 31 in the first container 20 is 4 or more and 12 or less, thereby preparing light gray AgHA.

Alternatively, the control device 19 may execute control so that the pH of the solution 31 in the first container 20 is 2 or more and 10 or less, thereby preparing white AgHA.

Synthesis pH of AgHA used by the control device 19 is appropriately adjusted depending on the purity of materials, a temperature, and Ag content.

The control device 19 controls the Ag content for HA to be 0.01% by weight or more and 30% by weight or less, more preferably 0.1% by weight or more and 15% by weight or less. When the Ag content for HA is 0.4% by weight or more, the antibacterial property of AgHA is greatly improved.

The control device 19 controls the temperature of the solution 31 so that the synthesis temperature at which the calcium hydroxide and the first mixed liquid are mixed to synthesize the AgHA suspension and the temperature at which the calcium hydroxide and the first mixed liquid are reacting are within a sixth range. The sixth range may be, for example, 5° C. or higher and 50° C. or lower. The sixth range may preferably be, such as, 5° C. or higher and 30° C. or lower. Although the temperature of the solution 31 tends to increase due to reaction heat during the AgHA preparation reaction, the operation of the control device 19 and the temperature adjustment device 25 can achieve a condition suitable for AgHA preparation.

The control device 19 may, for example, include a storage device 19a and a processor 19b. In this case, the storage device 19a stores software 19c. The storage device 19a may include a non-temporary storage device and a temporary storage device such as a cache memory. The software 19c may include a program and data. The processor 19b executes the software 19c stored in the storage device 19a and performs various controls for preparation of the light gray or white AgHA suspension 29.

When mixing the calcium hydroxide and the first mixed liquid (AgHA synthesis), the control device 19 executes control to cause the stirrer 26 to stir the solution 31 in the container 20. More specifically, the control device 19 transmits a signal indicating a rotation speed to the stirrer 26 when the second injection device 22 performs the dropping process of the first mixed liquid. For example, the control device 19 transmits a signal to the stirrer 26 to rotate the stirrer 26 at, for example, 50 rpm or higher and 1000 rpm or lower. More preferably, the control device 19 transmits a signal to the stirrer 26 to rotate the stirrer 26 at, for example, 100 rpm or higher and 500 rpm or lower.

After pouring out the supernatant portion of the solution 31 from the first container 20 and before pouring out the concentrated AgHA suspension 29 from the first container 20, the control device 19 executes control to cause the stirrer 26 to stir the concentrated AgHA suspension 29 in the first container 20. More specifically, the control device 19 transmits an instruction indicating the rotation speed to the stirrer 26 prior to pouring out the concentrated AgHA suspension 29. For example, the control device 19 transmits a signal to the stirrer 26 to rotate the stirrer 26 at, for example, 50 rpm or higher and 1000 rpm or lower. More preferably, the control device 19 transmits a signal to the stirrer 26 to rotate the stirrer 26 at, for example, 100 rpm or higher and 500 rpm or lower. This stirring by the stirrer 26 allows the concentration of the concentrated light or white AgHA suspension 29 to be uniform.

The control device 19 instructs the first pouring device 27 to pour out the supernatant portion of the solution 31 contained in the first container 20.

The control device 19 instructs the second pouring device 28 to pour out the settled portion (i.e., the concentrated AgHA suspension 29) of the solution 31 contained in the first container 20.

The first container 20 contains calcium hydroxide (solution) injected from the first injection device 21.

The first container 20 receives the first mixed liquid injected (e.g. dropped) by the second injection device 22.

In the first container 20, the calcium hydroxide and the first mixed liquid react to prepare (synthesize) the solution 31 including AgHA.

The first injection device 21 receives a signal indicating the concentration of calcium hydroxide from the control device 19. Based on the received signal, the first injection device 21 adjusts the concentration of calcium hydroxide and injects the calcium hydroxide with the adjusted concentration into the first container 20. In the second embodiment, the purity of the calcium hydroxide may be 90% or higher and 100% or lower.

The second injection device 22 receives a signal indicating the concentration of phosphoric acid, a signal indicating the concentration of silver nitrate, and a signal indicating the injection rate of the first mixed liquid from the control device 19. The second injection device 22 prepares the first mixed liquid by mixing phosphoric acid at the concentration indicated by the received signal and silver nitrate at the concentration indicated by the received signal, and drops the first mixed liquid at the concentration indicated by the received signal into the solution 31 containing calcium hydroxide stored in the first container 20 at the injection rate indicated by the received signal.

The pH meter 23 measures the pH of the solution 31 stored in the first container 20 and transmits a signal indicating the pH to the control device 19.

The thermometer 24 measures the temperature of the solution 31 stored in the first container 20 and transmits a signal indicating the temperature to the control device 19.

The temperature adjustment device 25 receives the signal indicating the temperature from the control device 19. The temperature adjustment device 25 executes temperature management (e.g., heating or cooling) of the solution 31 in the first container 20 so that the solution 31 in the first container 20 becomes the temperature indicated by the received signal during mixing of calcium hydroxide and the first mixed liquid (during AgHA synthesis) and during execution of spontaneous sedimentation on the solution 31.

The stirrer 26 receives a signal indicating the rotation speed from the control device 19. The stirrer 26 stirs the solution 31 in the container 20 according to the rotation speed indicated by the received signal. The stirrer 26 stirs the solution 31 during the dropping of the first mixed liquid (during AgHA synthesis). The stirrer 26 also stirs the concentrated AgHA suspension 29 before pouring out the concentrated AgHA suspension 29. There is a concentration gradient in the settled portion after the supernatant portion is poured out. In the second embodiment, the concentration of the settled portion can be made uniform by stirring the settled portion.

The first pouring device 27 receives a signal indicating a pouring instruction from the control device 19. Based on the received signal, the first pouring device 27 pours out the supernatant portion of the solution 31 from the first container 20, leaving the settled portion of the solution 31 (i.e., the concentrated light gray or white AgHA suspension 29) in the first container 20.

An inlet of the first pouring device 27 can be moved up and down according to a boundary position between the supernatant portion and the settled portion. More specifically, the height of the inlet of the first pouring device 27 is adjusted to be above the boundary position between the supernatant portion and the settled portion. This allows the supernatant portion to be efficiently poured out and the settled portion to remain in the first container 20.

The second pouring device 28 receives a signal indicating a pouring instruction from the control device 19. Based on the received signal, the second pouring device 28 injects the settled portion of the solution 31 in the first container 20 into the second container 30 for transport as a concentrated light gray or white AgHA suspension 29.

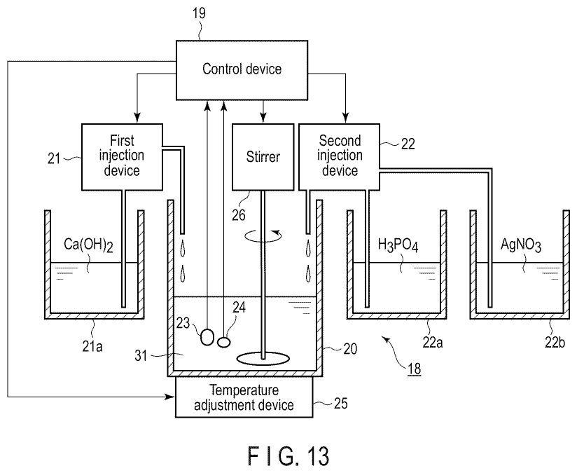

FIG. 13 is a conceptual diagram illustrating an example of a mixed state (AgHA synthesis state) of calcium hydroxide and the first mixed liquid by the preparation apparatus 18 according to the second embodiment. In this FIG. 13, the first pouring device 27 and the second pouring device 28 of the preparation apparatus 18 are omitted.

A third container 21a contains a solution of calcium hydroxide. The first injection device 21 adjusts the calcium hydroxide to the concentration indicated by the signal received from the control device 19, and injects the calcium hydroxide with the adjusted concentration into the first container 20.

A fourth container 22a contains a solution of phosphoric acid.

A fifth container 22b a solution of silver nitrate.

The second injection device 22 adjusts the phosphoric acid to the concentration indicated by the signal received from the control device 19. The second injection device 22 also adjusts the silver nitrate to the concentration indicated by the signal received from the control device 19. Further, the second injection device 22 prepares the first mixed liquid by mixing the phosphoric acid and the silver nitrate. Furthermore, the second injection device 22 drops the first mixed liquid with the adjusted concentration into the first container 20 at the dropping rate indicated by the signal received from the control device 20.

The control device 19 receives a signal indicating the pH of the solution 31 from the pH meter 23, and based on the pH of the solution 31, controls the operation of the first injection device 21 and the second injection device 22, and the stirring process of the stirrer 25.

The control device 19 receives a signal indicating the temperature of the solution 31 from the thermometer 24, and controls the operation of the temperature adjustment device 25 based on the temperature of the solution 31.

In the second embodiment, the first injection device 21 and the second injection device 22 may be, for example, tube pumps.

In FIG. 13, the fourth container 22a containing phosphoric acid and the fifth container 22b containing silver nitrate are used separately. However, the fourth container 22a and the fifth container 22b may be combined into one container. In this case, this one container contains the first mixed liquid obtained by mixing the phosphoric acid and the silver nitrate in advance. The second injector 22 sucks in the first mixed liquid in this one container and drips it into the solution 31 in the first container 20.

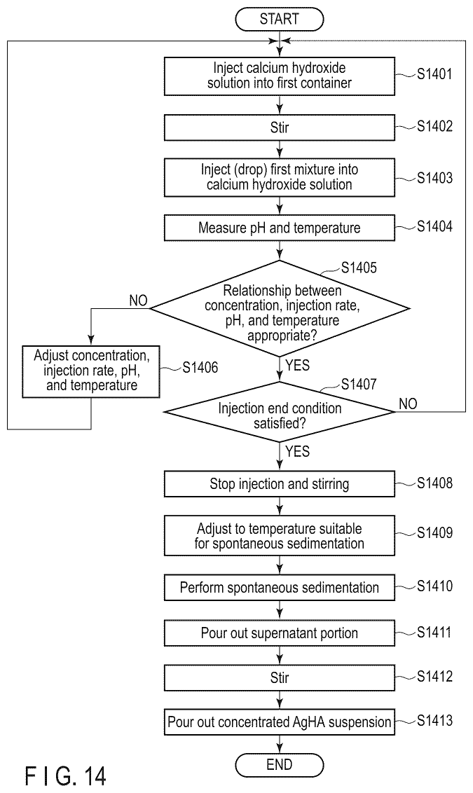

FIG. 14 is a flowchart illustrating an example of a method of preparing light gray or white AgHA suspension 29 executed by the preparation device 18 according to the second embodiment. The preparation method shown in FIG. 14 is executed in accordance with the control by the control device 19.

In S1401, the first injection device 21 injects calcium hydroxide into the first container 20 at the concentration specified by the control device 19.

In S1402, the stirrer 26 operates at the rotation speed specified by the control device 19 to stir the solution 31 in the first container 20.

In S1403, the second injection device 22 drops the first mixed liquid (first mixture) into the solution 31 (calcium hydroxide) in the first container 20 at the concentration and injection rate specified by the control device 19.

In S1404, the pH meter 23 measures the pH of the solution 31 in the first container 20 and transmits a signal indicating the pH to the control device 19, and the thermometer 24 measures the temperature of the solution 31 in the first container 20 and transmits a signal indicating the temperature to the control device 19.

In S1405, the control device 19 determines whether or not the relationship between the concentration of calcium hydroxide, the concentration and injection rate of the first mixed liquid, the pH of the solution 31 in the first container 20, and the temperature of the solution 31 satisfies a synthesis condition of light gray or white AgHA.

In a case where the control device 19 determines that the synthesis condition is not satisfied, in S1406, the control device 19 determines a new calcium hydroxide concentration, a new first mixed liquid concentration and a new first mixed liquid injection rate, a new pH, and a new temperature of the solution 31 in the first container 20. The control device 19 then transmits a signal indicating the new calcium hydroxide concentration to the first injection device 21. The first injection device 21 adjusts the concentration of calcium hydroxide based on the signal received from the control device 19. The control device 19 transmits a signal indicating the new first mixed liquid concentration and a signal indicating the new first mixed liquid injection rate to the second injection device 22. The second injection device 22 adjusts the concentration and the first injection rate of the first mixed liquid based on the signal received from the control device 2. The control device 19 transmits a signal indicating the new temperature to the temperature adjustment device 25. The temperature adjustment device 25 adjusts the temperature of the solution 31 based on the signal received from the control device 19. The process then returns to S1401.

Note that, in S1406 of the second embodiment, the control device 19 does not have to determine the new calcium hydroxide concentration and does not have to transmit a signal indicating the new calcium hydroxide concentration to the first injection device 21. In this case, the process returns to S1402.

In a case where the control device 19 determines that the synthesis condition is satisfied in S1405, in S1407, the control device 19 determines whether or not the end condition of the operation to drop the first mixed liquid on calcium hydroxide (condition for ending dropping) is satisfied.

The condition for ending dropping may be, for example, that the pH of the solution 31 in the first container 20 has reached a target range (target pH).

In the second embodiment, the target pH is, for example, a pH at which the ratio of the AgHA to be prepared is equal to or greater than a threshold value and the AgHA to be prepared is light gray or white.

After the pH of the solution 31 reaches the target pH, the pH of the solution 31 may increase after a while. Therefore, even after the pH of the solution 31 reaches the target pH, the control device 19 causes the second injection device 22 to drop the first mixed liquid again as appropriate thereafter, and, in the case where the pH of the solution 31 stabilizes, the control device 19 may determine that the condition for ending dropping is satisfied.

The condition for ending dropping may be, for example, that the ratio of the AgHA to be prepared is equal to or greater than a threshold value, the pH at which the AgHA to be prepared is light gray or white, and the amount of the solution 31 in the first container 20 exceed a threshold value.

The control device 19 may intentionally prepare calcium-deficient AgHA by lowering the pH of the solution 31 by additional drops of the first mixed liquid after dropping the first mixed liquid.

In the case where the control device 19 determines that the condition for ending is not satisfied, the process returns to S1401. Note that, in the case where the control device 19 does not determine the new calcium hydroxide concentration in S1406 of the second embodiment, the process may return to S1402.

In the case where the control device 19 determines that the ending condition is satisfied, in S1408, the control device 19 transmits stop signals to the first injection device 21, the second injection device 22, and the stirrer 26. The first injection device 21 and the second injection device 22 stop the injection operation according to the signals received from the control device 19. The stirrer 26 stops the stirring operation according to the signal received from the control device 19.

In S1409, the control device 19 transmits a signal indicating a temperature suitable for spontaneous sedimentation to the temperature adjustment device 25. The temperature adjustment device 25 adjusts the temperature of the solution 31 based on the signal received from the control device 19.

In step S1410, the spontaneous sedimentation of the solution 31 in the first container 20 is carried out for a predetermined period of time or longer.

In S1411, the first pouring device 27 pours out the supernatant portion of the solution 31 in the first container 20 according to the control by the control device 19, leaving the settled portion in the first container 20.

In S1412, the stirrer 26 stirs the

concentrated light gray or white AgHA suspension 29, which is the settled portion, in the first container 20 according to the control by the control device 19.

In S1413, the second pouring device 28 pours out the concentrated light gray or white AgHA suspension 29 in the second container 30 according to the control by the control device 19, and stores it in the second container 30.

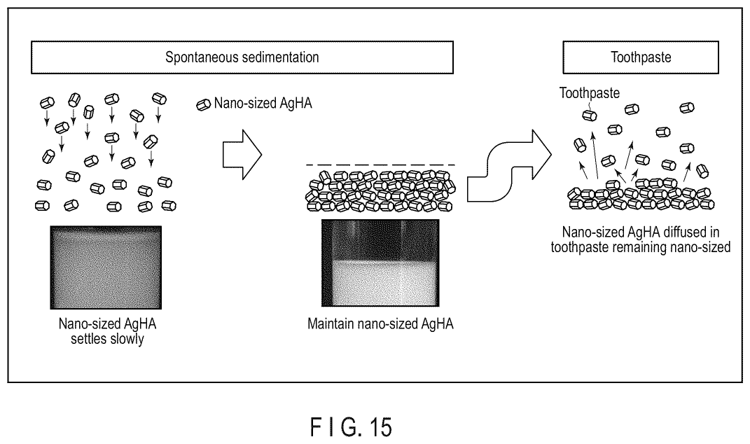

FIG. 15 is a conceptual diagram illustrating an example of spontaneous sedimentation in the method preparing the AgHA suspension 29 according to the second embodiment.

The solution 31 containing AgHA prepared in

the first container 20 is subjected to spontaneous sedimentation for a predetermined period of time. The predetermined period of time for spontaneous sedimentation may be, as a result of experiments, for example, from 1 to 60 days, or more preferably from 9 to 28 days.

The nano-sized AgHA in the solution 31 settles slowly. When the supernatant portion of the solution 31 is removed, the concentrated AgHA suspension 29, which is the settled portion of the solution 31, remains. The AgHA contained in this AgHA suspension 29 maintains its nanosize.

By mixing the concentrated AgHA suspension 29 with toothpaste, a toothpaste with diffused nano-sized AgHA can be prepared.

As described above, AgHA may have a color such as brown, gray, light gray, or white. In the second embodiment, the target pH is a pH at which the concentrated AgHA suspension 29 becomes light gray or white.

In the second embodiment, the AgHA suspension 29 is prepared using the first mixed liquid mixed phosphoric acid and silver nitrate. There is also a preparation method in which silver oxide is used as the Ag source instead of silver nitrate, but silver oxide does not dissolve in phosphoric acid, so in the second embodiment, silver nitrate is used as the Ag source.

In the second embodiment, an example is described in which Ag is used as the antibacterial heavy metal, but Cu may also be used as the antibacterial heavy metal. In this case, for example, Cu(NO3), Cu(NO4), or Cu(NO3)2 is used instead of silver nitrate, and CuHA suspension containing CuHA is prepared.

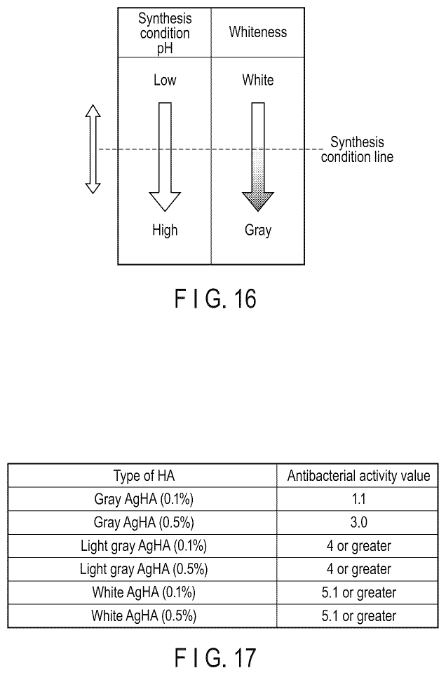

FIG. 16 is a diagram illustrating an example of the relationship of pH and color of the solution 31.

The lower the pH of the solution 31, the closer to white the color of AgHA in the solution 31 becomes.

The higher the pH of the solution 31, the further away from white the color of the AgHA in the solution 31 becomes, and the deeper the gray becomes.

In the second embodiment, the control device 19 controls the pH of the solution 31 so that the color of the AgHA is light gray or white, and the pH is a value such that the ratio of AgHA in the solution 31 exceeds a predetermined value.

The crystals of calcium-deficient AgHA have a structure that allows a greater amount of Ag uptake than AgHA crystals. Therefore, the higher the ratio of calcium-deficient AgHA, the higher the antibacterial effect of the prepared AgHA suspension 29.

White AgHA contains more calcium-deficient AgHA and has a greater amount of Ag uptake than gray AgHA.

FIG. 17 is a diagram illustrating an example of a results of applying gray AgHA, light gray AgHA, and white AgHA to nonwoven fabric and investigating antibacterial activity values using Escherichia coli.

FIG. 17 shows the results of investigating the antibacterial activity values for nonwoven fabric applied with a 0.1% AgHA solution and nonwoven fabric applied with a 0.5% AgHA solution. Here, the Ag content relative to HA for the AgHA contained in the AgHA solution is set to 2% by weight.

An antibacterial activity value of 2 or more and less than 3 indicates an antibacterial effect, and a value of 3 or more indicates a large antibacterial effect.

For light gray or white AgHA, a large antibacterial effect of 4 or more is obtained for both nonwoven fabric applied with a 0.1% by the weight AgHA solution and nonwoven fabric applied with a 0.5% by the weight.

It can be seen from FIG. 17 that the antibacterial effect of white AgHA is particularly large.

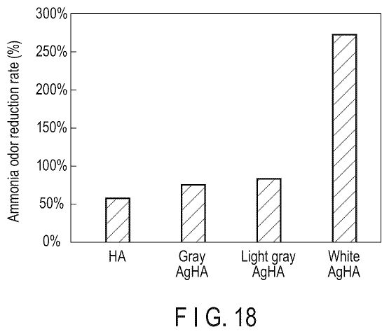

FIG. 18 is a graph illustrating examples of deodorizing effects of a nonwoven fabric coated with HA solution having a concentration of 0.5% by weight, a nonwoven fabric coated with light gray AgHA solution having a concentration of 0.5% by weight, and a nonwoven fabric coated with white AgHA solution having a concentration of 0.5% by weight. In FIG. 18, a vertical axis indicates the rate of reduction in ammonia odor. In the AgHA in FIG. 18, the Ag content relative to HA is 2% by weight.

Light gray AgHA has a stronger deodorizing effect than HA and gray AgHA.

White AgHA has a stronger deodorizing effect than light gray AgHA by about 4 to 5 times.

In the second embodiment described above, calcium-deficient AgHA is intentionally prepared to prepare AgHA with a high Ag content. This AgHA with a high Ag content has a light gray or white color.

The light gray or white AgHA prepared in the second embodiment has strong bactericidal and deodorizing effects.

In the second embodiment described above, in order to maintain the particle size of AgHA at about nano size, the solution 31 is prepared and concentrated, the concentrated AgHA suspension 29 is contained in the second container 30, and the second container 30 is transported.

In the second embodiment, for example, by adjusting various conditions such as the concentration of calcium hydroxide, the concentration of phosphoric acid, the injection rate of the first mixed liquid, and the temperature of the solution 31, the solution 31 containing AgHA with small particle size can be prepared and concentrated efficiently, and the pH of the solution 31 can be adjusted to achieve bacterial count control.

In the second embodiment, AgHA is shipped and utilized in a state of being contained in a suspension. Therefore, aggregation of AgHA particles can be suppressed, and AgHA with small particle size can be utilized.

In the second embodiment, concentration is performed by spontaneous sedimentation. Here, the differences between the spontaneous sedimentation used in the second embodiment and the concentration by a centrifuge, which is a comparative example, are explained. When the solution 31 is concentrated using a centrifuge, aggregation of AgHA particles occurs, making redispersion difficult. In contrast, in the second embodiment, since concentration is performed by spontaneous sedimentation, aggregation of AgHA particles can be suppressed. Concentration can also make the transportation of the AgHA suspension 29 more efficient and easier to handle.

Note that, in experiments, it was possible to

concentrate the suspension containing nano-sized AgHA by about four times through spontaneous sedimentation. In a case where the particle size of AgHA did not have to be nano-sized, the suspension could be concentrated to about 15%.

A period required for spontaneous sedimentation varied depending on the temperature of the solution 31 in the first container 20. For example, in experiments, the number of days required to concentrate to about 3% was nine to 28 days. It was obtained from data of preparing 200 100L-class AgHA suspensions 29 that spontaneous sedimentation is affected by the temperature atmosphere. From this result, in the second embodiment, the control device 19 controls the temperature of the solution 31 in the first container 20 to be at a temperature suitable for spontaneous sedimentation. In the preparation apparatus 1 according to the second embodiment, the sedimentation period could be shortened by performing spontaneous sedimentation at a temperature of 5° C. or higher and 40° C. or lower. Therefore, in the second embodiment, the solution 31 can be efficiently concentrated to prepare the AgHA suspension 29.

In the second embodiment, the concentrated suspension 31 is stirred by the stirrer 26 and then contained in the second container 29. Therefore, in the second embodiment, the concentration of the concentrated suspension 29 can be made uniform.

In the second embodiment, as a result of experiments, the effect of suppressing the number of bacteria was obtained by controlling the storage temperature of the solution 31 and the concentrated AgHA suspension 29 in the range of 2° C. or higher and 30° C. or lower. More preferably, the number of bacteria can be suppressed by controlling the storage temperature of the solution 31 and the concentrated AgHA suspension 29 in the range of 2° C. or higher and 20° C. or lower.

Therefore, the control device 19 and the temperature adjustment device 25 may control the temperature of the solution 31 and the temperature of the concentrated AgHA suspension 29 in the range of 2° C. or higher and 30° C. or lower, more preferably in the range of 2° C. or higher and 20° C. or lower.

In the second embodiment, the control device 19 and the temperature adjustment device 25 may control the temperature of the solution 31 during the sedimentation period in the range of 15° C. or higher and 25° C. or lower to shorten the sedimentation period, and after the sedimentation period has elapsed, control the temperature of the solution 31 and the concentrated AgHA suspension 29 in the range of 2° C. or higher and 20° C. or lower for suppressing the number of bacteria. In the second embodiment, the temperature adjustment device 25 may also regulate the temperature of the concentrated AgHA suspension 29 in the second container 30 in addition to regulating the temperature of the solution 31 in the first container 20. In this case, the control device 19 may use the temperature adjustment device 25 to control the temperature of the concentrated AgHA suspension 29 in the second container 30 in the range of 2° C. or higher and 20° C. or lower.

In the second embodiment, the solution 31 is concentrated by spontaneous sedimentation. However, the concentration may be executed by centrifugation using very weak centrifugal force to maintain the dispersibility of AgHA in the solution 31. Furthermore, in the second embodiment, the AgHA suspension concentrated by spontaneous sedimentation may be further concentrated in a centrifuge using weak centrifugal force. In this case, the stirrer 26 may be used to vigorously stir the AgHA suspension in order to disperse the AgHA within the concentrated AgHA suspension. In a case where concentration is performed using weak centrifugal force, it is possible to suppress AgHA aggregation to about 6% and prepare a concentrated AgHA suspension.

In the second embodiment, the case where the prepared solution 31 (AgHA suspension) is concentrated is described as an example. However, when concentration is not required, the solution 31 may be transferred to the second container 30 while being stirred by the stirrer 26. Alternatively, the solution 31 may be diluted with water, stirred by the stirrer 26, and transferred to the second container 30.

In the above-described first embodiment, AgHA obtained by drying the solution 31 of the second embodiment may be used as a target, or AgHA obtained by drying the condensed AgHA suspension 29 may be used as a target.

### Third Embodiment

In the above-described second embodiment, the second injection device 22 generates the first mixed liquid by mixing phosphoric acid and silver nitrate, and drops it into the solution 31 in the first container 20.

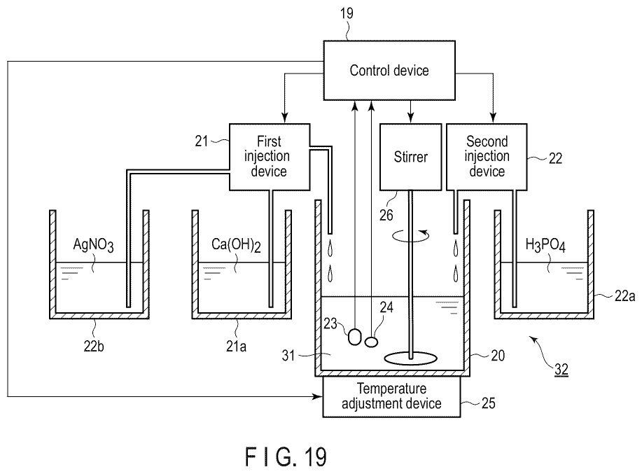

In contrast, in a preparation apparatus 32 according to a third embodiment illustrated in FIG. 19, a first injection device 21 mixes calcium hydroxide in a third container 21a and silver nitrate in a fifth container 22b to generate a second mixed liquid, and injects the second mixed liquid into a container 20. Then, a second injection device 22 drops phosphoric acid in a fourth container 22a into a solution 31 in the container 20.

The preparation apparatus 32 according to the third embodiment can prepare an AgHA suspension 29 containing AgHA that has a great antibacterial effect and deodorant effect and that is small in particle size as in the case of the second embodiment.

In the above-described first embodiment, AgHA obtained by drying the solution 31 of the third embodiment may be used as a target, or AgHA obtained by drying the condensed AgHA suspension 29 may be used as a target.

### Fourth Embodiment

In a fourth embodiment, hydrothermal treatment according to the above-described first embodiment will be described.

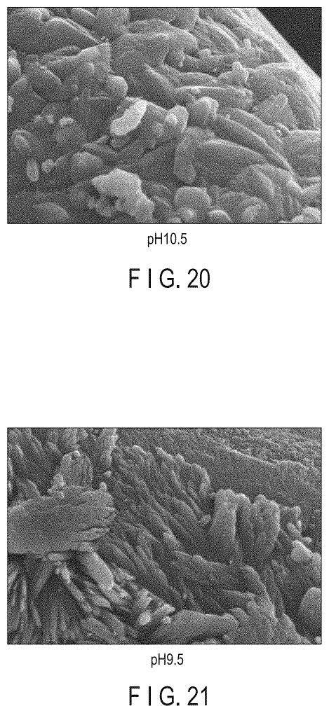

FIG. 20 is an enlarged view illustrating an example of a state of the thin film 11B in a case where the pH of the liquid 33 used for hydrothermal treatment is 10.5.

FIG. 21 is an enlarged view illustrating an example of a state of the thin film 11B in a case where the pH of the liquid 33 used for hydrothermal treatment is 9.5.

The size of crystals of the thin film 11B, the amount of dissolution of the thin film 11B during hydrothermal treatment, and the amount of dissolution of the thin film 11B in a living body differ between the cases where the pH of the liquid 33 used for hydrothermal treatment is 9.5 and 10.5.

To be specific, the size of the crystals of the thin film 11B in the case where the pH of the liquid 33 is 10.5 is smaller than the size of the crystals of the thin film 11B in the case where the pH of the liquid 33 is 9.5.

The amount of dissolution of the thin film 11B during hydrothermal treatment in the case where the pH of the liquid 33 is 10.5 is less than the amount of dissolution of the thin film 11B during hydrothermal treatment in the case where the pH of the liquid 33 is 9.5.

The amount of dissolution of the thin film 11B in the living body in the case where the pH of the liquid 33 is 10.5 is less than the amount of dissolution of the thin film 11B in the living body in the case where the pH of the liquid 33 is 9.5.

If the crystals of the thin film 11B are moderately small, nano-sized hydroxyapatite diffuses within the living body, showing a high affinity for bone, which is favorable for early bone formation.

Accordingly, it is preferable that the liquid 33 be an alkaline solution. Using an alkaline solution with a pH of 9.0 or greater for hydrothermal treatment can suppress the reduction of the film thickness. For example, a pH of 10.5 is preferable to a pH of 9.5.

The following description illustrates the crystallization results in cases where the liquid 33 used for hydrothermal treatment is NaOH, a mixed liquid of NaOH and silver nitrate, a mixed liquid of ammonia and silver nitrate, pure water, and a mixed liquid of pure water and silver nitrate.

If hydrothermal treatment is performed, using NaOH with a pH of 9.5 as the liquid 33, the amount of dissolution of Ag from the thin film 11B is suppressed. Accordingly, NaOH with a pH of 9.5 can be used as the liquid 33.

If hydrothermal treatment is performed using the mixed liquid of NaOH and silver nitrate with a pH of 7 as the liquid 33, the precipitation of silver hydroxide is confirmed in the liquid 33 after hydrothermal treatment. In addition, the thin film 11B after hydrothermal treatment is covered by silver oxide. Accordingly, it is not preferable to use the mixed liquid of NaOH and silver nitrate with a pH of 7 as the liquid 33.

If hydrothermal treatment is performed using the mixed liquid of ammonia and silver nitrate as the liquid 33, Ag precipitates during the hydrothermal treatment. Accordingly, it is not preferable to use the mixed liquid of ammonia and silver nitrate as the liquid 33.

If hydrothermal treatment is performed using the mixed liquid of pure water and silver nitrate as the liquid 33, Ag, Ca, and P included in the thin film 11B dissolves, and in particular, the dissolution of Ca and P is promoted. If neutral pure water is used for hydrothermal treatment, the film thickness may decrease by, for example, approximately 15% to 20%, during the hydrothermal treatment. However, if an alkaline solution with a pH of 9.0 or greater is used for hydrothermal treatment, the decrease of the film thickness can be suppressed to, for example, 5% or less.

The following description explains the relationship between an immersion period and a thin film residual rate in a case where the thin film 11B before hydrothermal treatment is immersed in a liquid, and the relationship between the immersion period and the thin film residual rate in a case where the thin film 11B after hydrothermal treatment is immersed in the liquid.

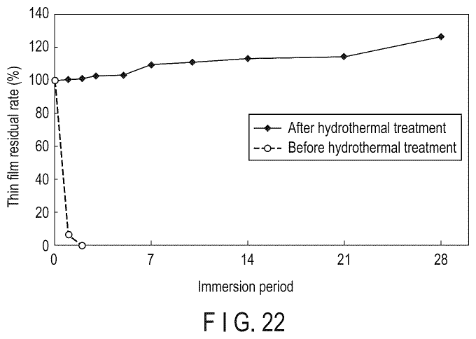

FIG. 22 is a graph illustrating an example of the relationship between the immersion period and the thin film residual rate in the case where the thin film 11B before hydrothermal treatment is immersed in the liquid, and an example of the relationship between the immersion period and the thin film residual rate in the case where the thin film 11B after hydrothermal treatment is immersed in the liquid.

In FIG. 22, the liquid in which the thin film 11B is immersed is cell culture medium. In the experiment, the temperature of the liquid is 37° C. and the immersion period is four weeks.

In FIG. 22, the thin film 11B before hydrothermal treatment disappears in approximately two days.

In contrast, in the case of the thin film 11B after hydrothermal treatment, as the immersion period becomes longer, the thin film 11B increases with Ca and P acting in a living body, and the thin film residual rate becomes higher.

Therefore, performing hydrothermal treatment on the thin film 11B, formed by sputtering, has a great technical significance.

The above-explained embodiments are mere examples and are not intended to limit the scope of the invention. The above-explained embodiments may be embodied in a variety of other forms; furthermore, various omissions, substitutions and changes in the form of the above-explained embodiments may be made without departing from the spirit of the inventions. The accompanying claims and their equivalents are intended to cover such forms or modifications as would fall within the scope and spirit of the inventions.

What is claimed is:

1. A formation apparatus of a hydroxyapatite-containing thin film, the formation apparatus comprising:
a sputtering device which forms a thin film of a material including an antibacterial metal and hydroxyapatite on a surface of an object by sputtering, the object being an artificial joint or a dental implant;
a hydrothermal treatment device which performs hydrothermal treatment on the object, on which the thin film is formed, using an alkaline solution;
a first control device which controls the sputtering device; and
a second control device which controls the hydrothermal treatment device,
the sputtering device comprising:
a first container;
a holder provided in the first container and used to place the object, on which the thin film is yet to be formed, on a first surface;
an electrode provided in the first container, including a second surface facing the first surface of the holder, and used to place the material on the second surface; and
an inert gas filling device which fills the first container with an inert gas,
the first control device switching a positive pole and a negative pole of the electrode at a predetermined frequency or higher, controlling the inert gas filling device to control a pressure in the first container, and controlling the sputtering device to make an atomic number ratio (calcium/phosphorus) of calcium to phosphorus in the thin film range from 1.0 to 3.0 and to make a thickness of the thin film range from 0.1 μm to 10 μm,
the hydrothermal treatment device comprising a second container which accommodates the object, on which the thin film is formed by the sputtering device,
the second control device performing the hydrothermal treatment, with the thin film at a temperature of 100° C. to 180° C., using the alkaline solution with a pH of 9 to 11, and adjusting a pressure in the second container by changing the temperature during the hydrothermal treatment.

2. The formation apparatus of claim 1, wherein
the pH of the alkaline solution is 10.5 or greater.

3. The formation apparatus of claim 1, wherein
the first control device executes control to make the thickness of the thin film range from 1 μm to 2 μm.

4. The formation apparatus of claim 1, wherein
the antibacterial metal is silver,
in the material, {a weight of the silver/(the weight of the silver+a weight of the hydroxyapatite)}, calculated based on the weight of the silver and the weight of the hydroxyapatite, is 0.2 or greater, and
an antibacterial activity value of the thin film is 6 or greater.

5. A formation method of a hydroxyapatite-containing thin film, the formation method comprising:
forming a thin film of a material including an antibacterial metal and hydroxyapatite on a surface of an object by sputtering, the object being an artificial joint or a dental implant; and
performing hydrothermal treatment on the object, on which the thin film is formed, using an alkaline solution,
the sputtering comprising:
providing the object, on which the thin film is yet to be formed, on a first surface of a holder in a first container, and providing the material on a second surface of an electrode facing the first surface of the holder in the first container;
filling the first container with an inert gas; and
switching a positive pole and a negative pole of the electrode at a predetermined frequency or higher, controlling the filling with the inert gas to control a pressure in the first container, and forming the thin film on the object to make an atomic number ratio (calcium/phosphorus) of calcium to phosphorus in the thin film range from 1.0 to 3.0 and to make a thickness of the thin film range from 0.1 μm to 10 μm,
the hydrothermal treatment comprising:
accommodating the object, on which the thin film is formed by the sputtering, in a second container; and
using the alkaline solution with a pH of 9 to 11, with the thin film at a temperature of 100° C. to 180° C., and adjusting a pressure in the second container by changing the temperature.
